(19) United States
(12) Patent Application Publication
(10) Pub. No.: US 2026/0322379 A1
(43) Pub. Date: Oct. 15, 2026

(54) Gate Reduction in Adiabatic Logic

(71) Applicant: Bitdeer, Inc., San Jose, CA (US)

(72) Inventor: Stephen M. Beccue, Salmon, ID (US)

(21) Appl. No.: 19/176,557

(22) Filed: Apr. 11, 2025

(51) Int. Cl. H03K 19/00

(52) U.S. Cl. CPC H03K 19/0019; G06F 1/10

(57) ABSTRACT

An adiabatic logic system includes a pipeline of first, second, third and fourth adiabatic logic gates cascaded in a first path, a fifth adiabatic logic gate configured in a second path that converges with the first path, and a power clock generator. The power clock generator is operable to generate quadrature first, second, third and fourth power clock phases P1, P2, P3 and P4 for the first, second, third and fourth adiabatic logic gates and an additional fifth power clock phase P5 for the fifth adiabatic logic gate. The power clock generator generates the fifth power clock phase P5 so that as the adiabatic logic system operates the hold intervals of the fifth power clock phase P5 overlap the evaluation intervals of the fourth power clock phase P4, thus satisfying a critical hold time required by the fourth adiabatic logic gate and obviating the need for phase-correction buffers in the second path.

### BACKGROUND OF THE INVENTION

Digital integrated circuits (ICs) are commonly fabricated using complementary metal-oxide-semiconductor (CMOS) technology. However, given that CMOS logic gates dissipate significant amounts of power, particularly when switching between output logic states, other lower-power logic approaches have been sought over the years. One approach is a logic class known as “adiabatic logic” (or “charge recovery logic”). In general, the term “adiabatic” refers to a thermodynamic process in which no heat or energy is exchanged between the system and the external environment. Although the thermodynamical operation of an electronic circuit (the “system” in this case) can never be fully adiabatic, the term is nevertheless used in the electronics arts to emphasize the fact that in such ‘adiabatic’ circuits little heat is generated and undesirably lost to the external environment.

Adiabatic logic gates operate according to an oscillating power supply, often referred to as the “power clock” since it serves the dual purpose of supplying power to the adiabatic logic gate and controlling the gate's timing. In a typical adiabatic logic system 100 (see FIG. 1A), four cascaded adiabatic logic gates 102, 104, 106 are controlled and powered by a four-phase trapezoidal power clock (see FIG. 1B). Each power clock phase P1, P2, P3 and P4 has evaluation (E), hold (H), charge recovery (R), and wait (W) intervals, and each is configured to control one of the four cascaded adiabatic logic gates 102, 104, 106 and 108.

Data in the adiabatic logic system 100 is processed in a pipeline fashion. When one of the adiabatic logic gates 102, 104, 106 or 108 in the pipeline is operating within the evaluation interval of its corresponding power clock phase, a second adiabatic gate just before it in the pipeline is operating in its hold interval, thereby giving the first adiabatic logic gate sufficient time to capture and use the second adiabatic logic gate's output as an input, and a third adiabatic logic gate in the pipeline just after the first adiabatic logic gate waits for its next evaluation interval to arrive, which occurs right after the evaluation interval of the first adiabatic gate ends. By ramping the power clock phases P1, P2, P3 and P4 up and down during the evaluation and charge recovery intervals, the maximum current flowing in the output networks of the adiabatic logic gates 102, 104, 106 and 108 during changes in output logic states can be significantly reduced compared to the much higher currents that develop in the output networks of CMOS logic gates. Charge stored in the output load capacitances of the adiabatic logic gates 102, 104, 106 and 108 is also recycled back to the energy reservoir of the power clock generator during the charge recovery (R) intervals, further enhancing the energy efficiency of the adiabatic logic system.

Because data in adiabatic logic systems is processed in a pipeline fashion, adiabatic logic systems must be carefully designed so that sufficient setup and hold times are provided for and by all adiabatic logic gates in the system. Furthermore, for adiabatic logic systems that have converging paths, special care must be taken so that the data arriving at the point of convergence is properly synchronized. Whenever there is a disparity in adiabatic logic gates among two or more converging paths in a conventional adiabatic logic system, synchronization requires one or more phase-correction buffers to be introduced. For example, in the conventional adiabatic logic system 200 depicted in FIG. 2, which has first and second paths that converge at the inputs of adiabatic logic gate 204, two phase-correction buffers 208 are required to ensure that the data output from adiabatic logic gate 206 and the data output from adiabatic logic gate 202 are properly synchronized when appearing as inputs to adiabatic logic gate 204. The phase-correction buffers, though necessary in conventional adiabatic logic systems, are highly undesirable since they take up significant die area and compromise the energy efficiency of the adiabatic logic system 200. Their presence is especially problematic in adiabatic logic systems having many logic gates and many converging paths. The present invention provides a solution to this problem.

### BRIEF SUMMARY OF THE INVENTION

An adiabatic logic system and a method of its operation are disclosed. In one exemplary embodiment of the invention, the adiabatic logic system includes a pipeline of first, second, third and fourth adiabatic logic gates cascaded in a first path, a fifth adiabatic logic gate configured in a second path that converges with the first path, and a power clock generator. The power clock generator is operable to generate quadrature first, second, third and fourth power clock phases P1, P2, P3 and P4 for the first, second, third and fourth adiabatic logic gates and an additional fifth power clock phase P5 for the fifth adiabatic logic gate. The power clock generator generates the fifth power clock phase P5 so that as the adiabatic logic system operates the hold intervals of the fifth power clock phase P5 overlap the evaluation intervals of the fourth power clock phase P4, thus satisfying a critical hold time required by the fourth adiabatic logic gate and obviating the need for phase-correction buffers in the second path.

Further features and advantages of the invention, including a detailed description of the above-summarized and other exemplary embodiments of the invention, will now be described in detail with respect to the accompanying drawings, in which like reference numbers are used to indicate identical or functionally similar elements.

### BRIEF DESCRIPTION OF THE DRAWINGS

FIG. 1A is a schematic drawing of a conventional four-phase adiabatic logic system;

FIG. 1B is timing diagram of the four-phase power clock P1, P2, P3, P4 used to control and supply power to the conventional four-phase adiabatic logic system depicted in FIG. 1;

FIG. 2 is a schematic drawing of a typical four-phase adiabatic logic system with converging first and second paths, highlighting the necessity of phase-correction buffers in the second path in order to properly synchronize data flow at the gate of convergence;

FIG. 3A is a schematic drawing of an adiabatic logic system, according to one embodiment of the present invention;

FIG. 3B is a timing diagram of the five-phase power clock P1, P2, P3, P4, P5 that controls the operation of the adiabatic logic system depicted in FIG. 3A, in accordance with one embodiment of the present invention;

FIG. 4 is a block diagram of a stepwise power clock generator that may be used to implement the power clock generator of the adiabatic logic system depicted in FIG. 3A, according to one embodiment of the present invention;

FIG. 5 is a schematic drawing of one of the unit capacitor cells used in the stepwise power clock generator depicted in FIG. 4;

FIG. 6 is a drawing depicting a series of snapshots of the stepwise power clock generator depicted in FIG. 4 for a circumstance in which the stepwise power clock generator has M=5 unit capacitor cells, highlighting how various switches in the stepwise power clock generator are controlled in the process of generating the first power clock phase P1 of the five-phase power clock P1, P2, P3, P4, P5;

FIG. 7 is a timing diagram of the first power clock phase P1 generated by the stepwise power clock generator depicted in FIG. 6, for a circumstance in which the stepwise power clock generator has M=5 unit capacitor cells;

FIG. 8 is a timing diagram of the five-phase power clock P1, P2, P3, P4, P5 generated by the stepwise power clock generator depicted in FIG. 4 for a circumstance in which the stepwise power clock generator has M=5 unit capacitor cells, highlighting the ninety-degree phase-offset relationship among the first four power clock phases P1, P2, P3, P4 and salient waveform characteristics of the fifth power clock phase P5;

FIG. 9 is a timing diagram of a five-phase power clock P1, P2, P3, P4, P5 that controls the operation of the adiabatic logic system depicted in FIG. 3A, in accordance with another embodiment of the present invention; and

FIG. 10 is a diagram of a conventional 8-bit Brent-Kung parallel prefix adder, highlighting the number of gates and phase-correction buffers used in its implementation.

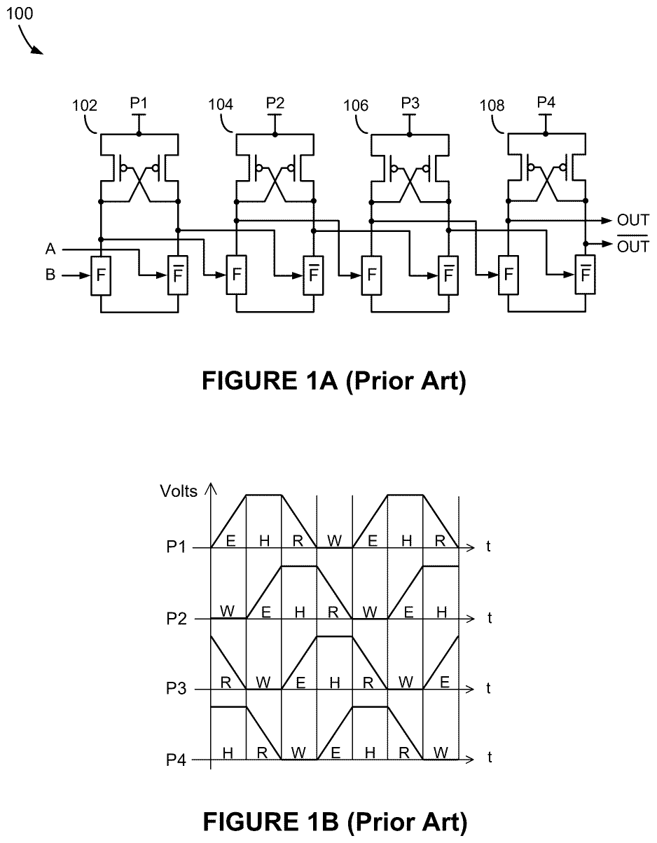

### DETAILED DESCRIPTION

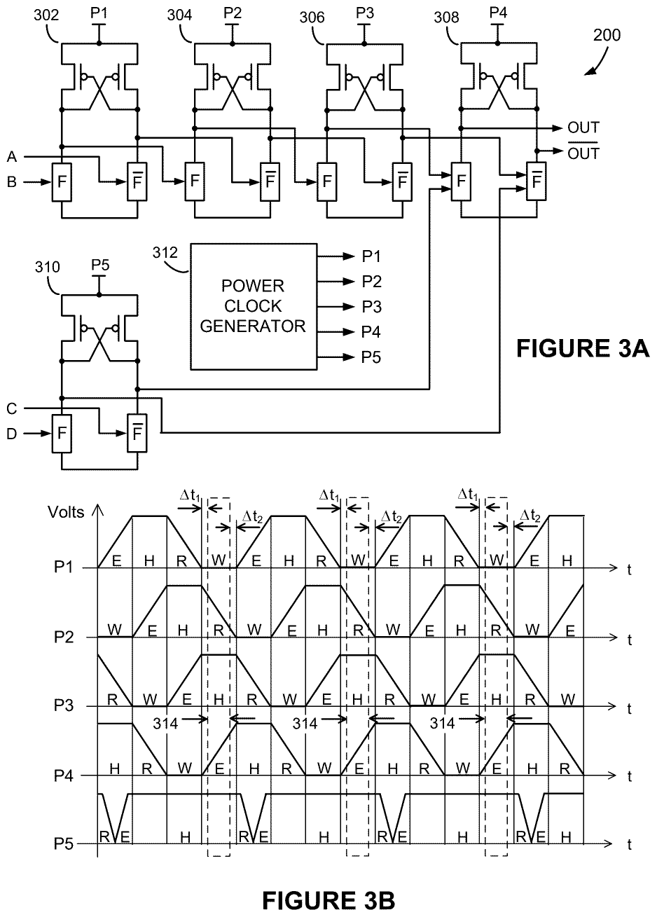

Referring to FIG. 3A there is shown an adiabatic logic system 300 according to one embodiment of the present invention. The adiabatic logic system 300 comprises a first path including first, second, third and fourth pipelined adiabatic logic gates 302, 304, 306, 308; a second path including a fifth adiabatic logic gate 310, and a power clock generator 312. The adiabatic logic system 300 will typically form part of a much larger adiabatic logic system containing tens, hundreds, thousands, or even more adiabatic logic gates fabricated in an integrated circuit, with many converging paths. However, in order to simplify the description of the present invention and best highlight its important attributes, just this small portion of what might be a much larger adiabatic logic system is highlighted. Further, whereas the adiabatic logic gates 302, 304, 306, 308 and 310 are depicted in FIG. 3A as comprising Efficient Charge Recovery Logic (ECRL) adiabatic logic gates, those of ordinary skill in the art will appreciate and understand that the present invention is not restricted to any adiabatic logic family. For example, rather than ECRL, the adiabatic logic gates 302, 304, 306, 308 and 310 can be implemented using Positive Feedback Adiabatic Logic (PFAL).

Before continuing it should be made clear what the term “adiabatic” means in the context of the present invention. In general, the term “adiabatic” refers to a thermodynamic process in which no heat or energy is exchanged between the system and the external environment. Although no electronic circuit (the “system” in this case) can be fully adiabatic, since any practical circuit must always dissipate some heat to the surrounding environment, it should be appreciated and understood, as it is appreciated understood by those of ordinary skill in the pertinent art, that the term “adiabatic” is nevertheless often and routinely used in the low-power electronic arts to refer to classes of electronic circuits and systems that use charge recovery logic (also referred to as “reversible logic”) to conserve energy. That same convention and meaning of the word “adiabatic” is used in the following detailed description of the present invention, and should also be recognized, appreciated, and understood when construing any appended claim that includes the word “adiabatic.”

The power clock generator 312 is operable to produce a five-phase power clock P1, P2, P3, P4 and P5. The first four power clock phases P1, P2, P3 and P4 are used to control the pipelined first, second, third and fourth adiabatic logic gates 302, 304, 306, 308 in the first path, similar to as in a conventional four-phase adiabatic logic system, with the four power clock phases P1, P2, P3 and P4 being in quadrature (i.e., each being phase-offset from one another by ninety degrees) and each having respective evaluation (E), hold (H), charge recovery (R) and wait intervals (W), as can be seen in the timing diagram of the adiabatic logic system 300 depicted in FIG. 3B.

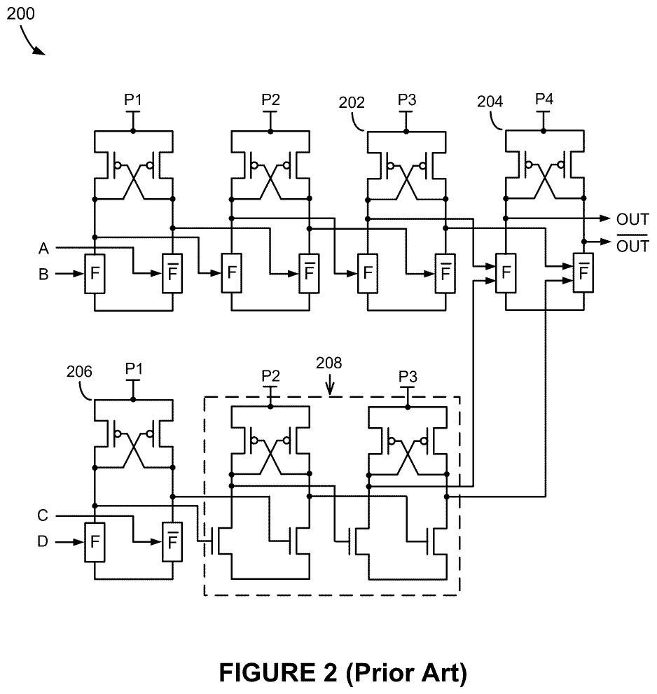

Also shown in FIG. 3B is the fifth power clock phase P5, which controls the operation of the fifth adiabatic logic gate 310 in the second path. The power clock generator 312 is configured to generate the fifth power clock phase P5 so that its hold intervals overlap the evaluation intervals of the fourth power clock phase P4, thus ensuring that the data outputs of the third and fifth adiabatic logic gates 306 and 310 are in timed alignment when presented as inputs to the fourth adiabatic logic gate 308 and while the fourth adiabatic logic gate 308 is operating in its evaluation interval. Unlike the prior art approach 200 described above (compare FIG. 3A to prior art FIG. 2), no phase-correction buffers are required to synchronize the input data.

Reference numerals 314 and associated dashed boxes in FIG. 3B are used to denote what may be referred to as the “critical hold time” 314. The critical hold time 314 is the time needed for fourth adiabatic logic gate 308 to properly capture as input data the output data produced by the third and fifth adiabatic logic gate 306 and 310. Accordingly, the adiabatic logic system 300 will work properly and adiabatically so long as the fifth power clock phase P5 honors the critical hold time 314. If desired or necessary, additional power clock phases (i.e., P6, P7, etc.) can be generated by the power clock generator 312 to obviate the need for even more phase-correction buffers in other converging paths, and the adiabatic logic system 300 will continue operating properly and adiabatically, again so long as each additional power clock phase honors the critical hold time 314.

FIG. 3B also illustrates how from the end of each wait interval of the fourth power clock phase P4 to the beginning of each critical hold time 314, the voltage of the fourth power clock phase P4 is less than |Vth, p|, where V_{th,p} is the threshold voltage of each of its cross-coupled PMOS transistors. During those times Δt₁ the fourth adiabatic logic gate 308 is not yet able to evaluate its input, so, in relation to the fourth power clock phase P4 at least, nothing of interest occurs during those times Δt₁. The timing diagram further reveals that once the fourth adiabatic logic gate 308 has completed evaluating its inputs, which occurs at the ends of each critical hold time 314, there are times Δt₂ during which nothing of interest occurs, again, at least in relation to the fourth power clock P4. The Δt₁ and Δt₂ time periods are therefore extraneous and can be ignored or exploited if desired or necessary in the generation of the fifth power clock phase P5.

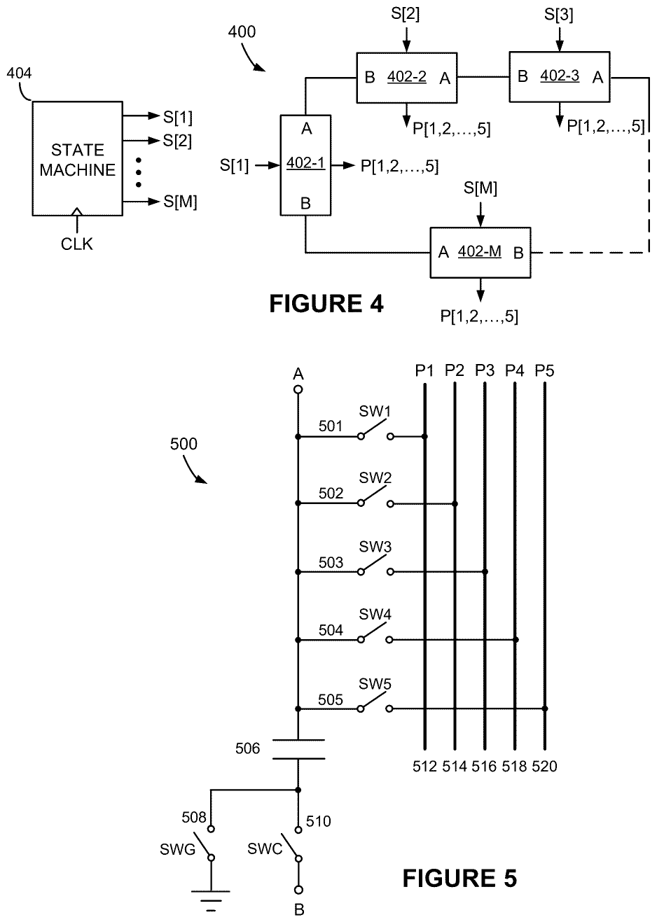

The power clock generator 312 can be implemented in various ways. For example, a ring oscillator, multiple phase-locked loops (PLLs), a driven set of delays lines, or a plurality of LC oscillators can be used. While any one of these approaches can be used, in a preferred embodiment of the present invention a stepwise power clock generator 400 like that depicted in FIG. 4 is used. The stepwise power clock generator 400 is similar to the switched-capacitor clock synthesizer described in co-pending and commonly-assigned U.S. patent application No. Ser. No. 19/176,438, entitled “Switched-Capacitor Clock Synthesizer for Nonlinear Loads,” which is incorporated herein by reference.

As shown in FIG. 4, the stepwise power clock generator 400 comprises a plurality of unit capacitor cells 402-1, 402-2, 402-3, . . . , 402-M configured in a loop, where M denotes the number of unit capacitor cells used. Each unit capacitor cell 402-1, 402-2, 402-3, . . . , 402-M has a first unit capacitor cell terminal (labeled terminal “A” in FIG. 4) and a second unit capacitor cell terminal (labeled terminal “B”) so that when configured in the loop terminal A of any given unit capacitor cell is coupled to terminal B of an adjacent unit capacitor cell. The unit capacitor cells 402-1, 402-2, 402-3, . . . , 402-M are controlled by a corresponding plurality of switch control sets S[1], S[2], S[3], . . . , S[M] generated and provided by a state machine 404, and the unit capacitor cells 402-1, 402-2, 402-3, . . . , 402-M are collectively operable to generate a plurality of phase-offset power clocks, which in this example comprise the five-phase power clock P1, P2, P3, P4 and P5 for the adiabatic logic system 300 depicted in FIG. 3A.

FIG. 5 is a schematic drawing illustrating in more detail how each of the unit capacitor cell 402-1, 402-2, 402-3, . . . , 402-M may be constructed. As shown, each unit capacitor cell 500 comprises first, second, third, fourth and fifth output switches 501, 502, 503, 504 and 505; a capacitor 506; a ground-connect switch 508; and a loop switch 510. A first terminal of the capacitor 506 is connected to the first unit capacitor cell terminal (i.e., terminal A), and a second terminal of capacitor 506 is selectively coupled to the second unit capacitor cell terminal (i.e., terminal B), depending on whether loop switch 510 is open (i.e., is “off”) or closed (i.e., is “on”). The first, second, third, fourth and fifth output switches 501, 502, 503, 504 and 505 are coupled between the first terminal of capacitor 506 and corresponding output signal buses 512, 514, 516, 518 and 520 or, alternatively, between the second terminal of capacitor 506 and the corresponding output signal buses 512, 514, 516, 518 and 520. Further, the first, second, third, fourth and fifth output switches 501, 502, 503, 504 and 505 are controlled by corresponding output-switch control signals SW1-SW5. Ground-connect switch 508 is coupled between the second terminal of capacitor 506 and ground, and is controlled by ground-connect switch control signal SWG. Loop switch 510 is also connected to the second terminal of capacitor 506, and is controlled by loop-switch control signal SWC.

When a plurality of unit capacitors cells 500 is configured in a loop, as in FIG. 4, one of the ground-connect switches 508 in a given one of the unit capacitor cells 500-1, 500-2, . . . , 500-M is closed, thereby establishing a ground reference for the stepwise power clock generator 400, and the loop switch 510 in the given unit capacitor cell remains open, connecting terminal B of the given unit capacitor cell to terminal A of its adjacent unit capacitor cell. Meanwhile, the ground-connect switches 508 in all remaining unit capacitor cells remain open and the loop switches 510 in all remaining unit capacitor cells remain closed, thereby effectively connecting all capacitors 506-1, 506-2, . . . , 506-M in the plurality of the unit capacitors cells 500-1, 500-2, . . . , 500-M in series. The resulting capacitor bank is periodically charged and refreshed by an external power supply so that the capacitor bank optimally maintains a voltage across it of Vdd and so that each of the capacitors 506-1, 506-2, . . . , 506-M in the capacitor bank optimally maintains a voltage drop of Vdd/M.

The stepwise power clock generator 400 is operable to generate a five phase-offset stepwise trapezoidal power clock P1, P2, P3, P4 and P5 on output signal buses 512, 514, 516, 518 and 520. Note that the output signal buses 512, 514, 516, 518 and 520 are shared by, in other words, are common among, the plurality of the unit capacitors cells 500-1, 500-2, . . . , 500-M.

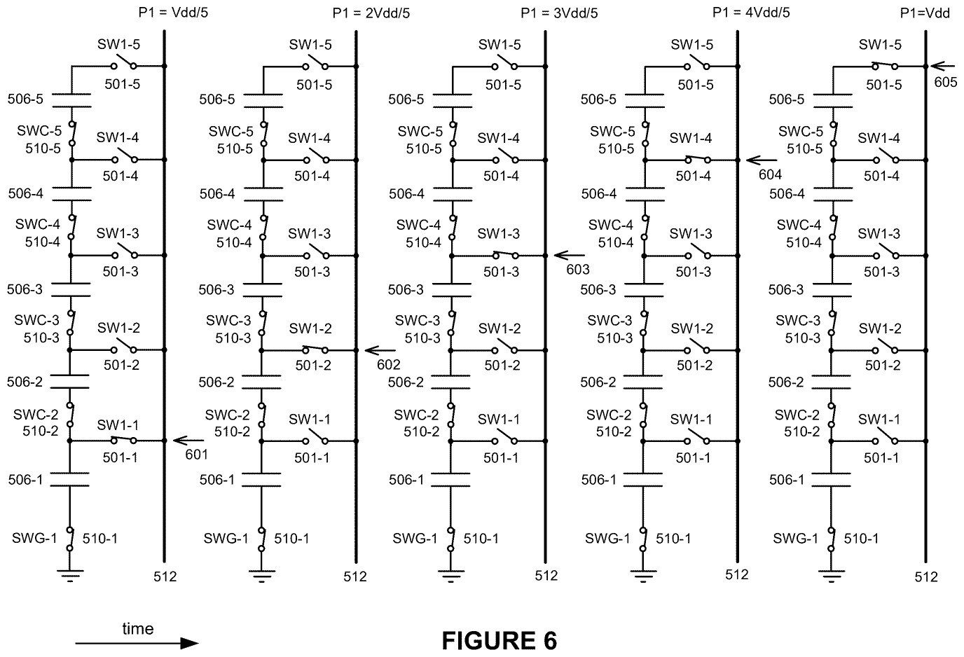

FIG. 6 is a drawing illustrating in a series of snapshots how first output switches 501-1, 501-2, . . . , 501-5 in the plurality of unit capacitor cells 500-1, 500-2, . . . , 500-5 are controlled in the process of generating the first power clock phase P1 on first-phase output signal bus 512. It is assumed in this example that ground-connect switch 510-1 is closed, thereby making capacitor 506-1 in unit capacitor cell 501-1 the ground reference for the capacitor bank. For ease and clarity it is also assumed that M=5, it being understood that in an actual application M would likely be much greater than 5. During operation, first-output switches 501-1, 501-2, . . . , 501-5 in unit capacitor cells 500-1, 500-2, . . . , 500-5 are closed and opened in sequence (see reference arrows 601-605 in FIG. 6), under the control of first-phase switch control signals SW1-1, SW1-2, . . ., SW1-5, thereby cumulatively increasing the number of capacitors 506-1, 506-2, . . . , 506-5 that are coupled in series between first-phase output signal bus 512 and ground. The accumulation of capacitors between the first-phase output signal bus 512 and ground results in the output voltage on first-phase output signal bus 512 ramping up in voltage steps of Vdd/5. When the plateau voltage Vdd is reached, first-output switch 501-5 is held closed for a quarter cycle, after which time first-output switches 501-1, 501-2, . . . , 501-5 are sequentially closed and opened in a reverse order from that during the ramp-up quarter cycle, thereby successively subtracting the number of capacitors 506-1, 506-2, . . . , 506-5 that are coupled in series between first-phase output signal bus 512 and ground and consequently ramping down the output voltage in stepped decrements of Vdd/5. Finally, after the output voltage has reached its minimum, the minimum voltage is held for a quarter cycle. This completes the first full cycle of the first power clock phase P1. The above-described process is repeated indefinitely to thereby produce the desired periodic first power clock phase P1 on first-phase output signal bus 512.

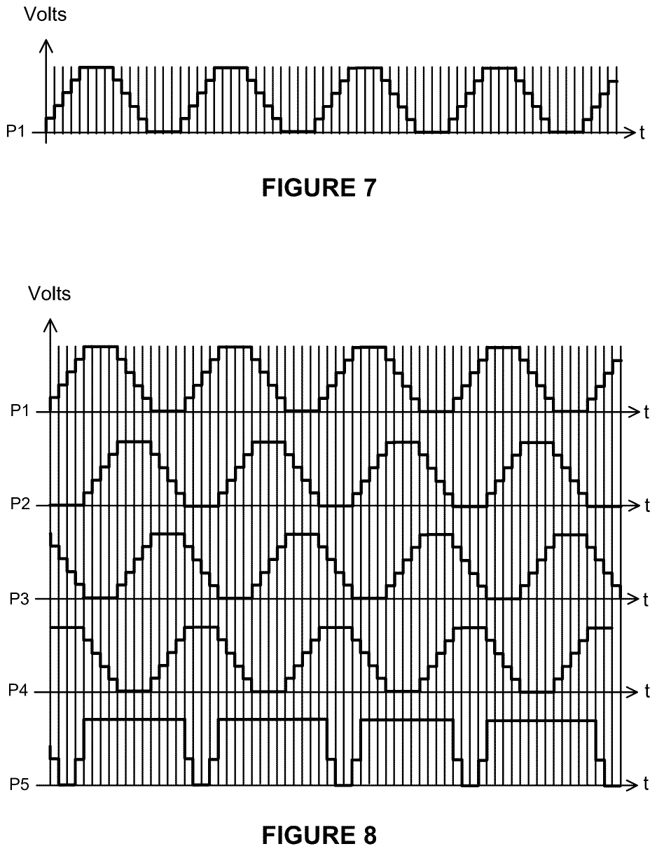

FIG. 7 is a timing diagram showing the stepwise trapezoidal waveform of the first power clock phase P1 generated by the stepwise power clock generator 400, for the circumstance in which M=5. The second, third and fourth power clock phases P2, P3 and P4, which control the operation of the second, third and fourth adiabatic logic gates 304, 306 and 308 in the first path of the adiabatic logic system 300 are generated similarly but using switch sets: 502-1, 502-2, . . . , 502-5; 503-1, 503-2, . . . , 503-5; and 504-1, 504-2, . . . , 504-5, each switch set controlled by corresponding switch control sets: SW2-1, SW2-2, . . . , SW2-5; SW3-1, SW3-2, . . . , SW3-5; and SW4-1, SW4-2, . . ., SW4-5 generated and provided by state machine 404, and each switch control set successively delayed by a quarter cycle so that the final first, second, third and fourth power clock phases P1, P2, P3 and P4 produced on first-phase, second-phase, third-phase and fourth-phase output signal buses 512, 514, 516 and 518 are in quadrature, as can be observed in FIG. 8.

FIG. 8 further shows the fifth power clock phase P5 generated by the stepwise power clock generator 400 on fifth-phase output signal bus 520, again for the case where M=5. As was explained above, the fifth power clock phase P5 controls the operation of fifth adiabatic logic gate 310 in the second path of the adiabatic logic system 300 depicted in FIG. 3A, its hold intervals overlapping the evaluation intervals of the fourth adiabatic logic gate 308, as illustrated in FIGS. 3B and 8.

One undesirable characteristic of the fifth power clock phase P5 depicted in FIG. 8 (and FIG. 3B) is that it has shorter evaluation (E) and charge recovery (R) intervals (steeper dV/dt slopes) than the relatively longer evaluation and charge recover intervals of the first, second, third and fourth power clock phases P1, P2, P3 and P4. The shorter durations result in the fifth adiabatic logic gate 310 being less energy efficient than the first, second, third and fourth adiabatic logic gates 302, 304, 306, 308.

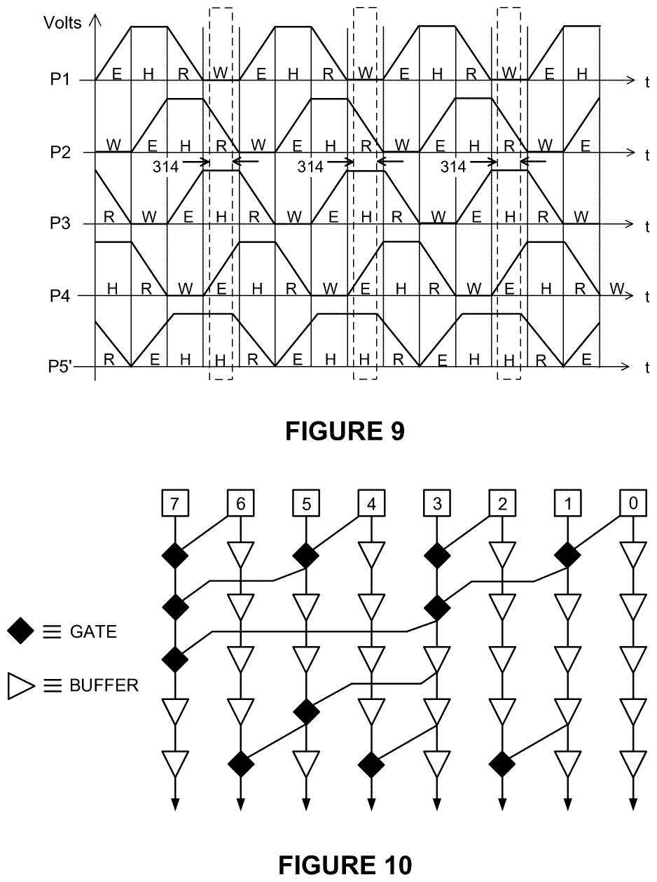

Depending on the power clock frequency and required critical hold time 314, it may not be possible to increase the durations of the fifth power clock phase's P5′s evaluation and charge recovery intervals, in other words, it may not be possible to reduce the slopes dV/dt of P5 in the evaluation and charge recovery intervals. However, to the extent that it is possible, the stepwise power clock generator 400 can be easily adapted to do so. For example, the stepwise power clock generator 400 can be adapted to generate the alternative fifth power clock phase P5′ depicted in FIG. 9. Compared to the fifth power clock phase P5 depicted in FIGS. 3B and 8, the alternative fifth power clock phase P5′ is seen to have shorter hold time intervals, yet the shorter hold times are still of sufficient duration to satisfy the setup requirements of the fourth adiabatic logic gate 308. The alternative fifth power clock phase P5′ also exploits the fact that the fourth adiabatic logic gate 308 completes each one of its evaluations a time Δt₂ before each one of its hold intervals begins (see FIG. 3B), thus effectively ignoring the extraneous Δt₂ times. Both attributes result in the alternative fifth power clock phase P5′ having longer evaluation and charge recovery intervals (i.e., gentler dV/dt evaluation and charge recovery slopes) compared to the relatively shorter evaluation and charge recovery intervals of the fifth power clock phase P5.

Whatever timing constraints may be imposed on the fifth power clock phase P5, the stepwise power clock generator 400 has the adaptability to accommodate them.

For example, if the critical hold time 314 demands shorter evaluation and/or charge recovery intervals (steeper dV/dt slopes), the stepwise power clock generator 400 can be adapted so that only every other one of the fifth-phase output switches 505-1, 505-2, . . . , 501-M is closed and opened during the generation of the fifth power clock phase P5, in other words, instead of closing and opening each and every one of the switches 505-1, 505-2, . . . , 501-M in succession, thereby increasing the magnitude(s) of one or more of the voltage steps generated and consequently reducing the durations of the evaluation and charge recovery intervals of the fifth power clock phase. Or the ground reference of the power clock generator 400, which, as explained above, is determined by which one of the ground-connect switches ground-connect switches 508-1, 508-2, . . . , 508-M in the plurality of unit capacitor cells 500-1, 500-2, . . . , 500-M is closed, can be dynamically changed in a manner that either shortens or lengthens the evaluation and/or charge recovery intervals. Yet another approach would be to vary the duration(s) of one or more of the voltage steps in the process of generating the fifth power clock phase P5, and thereby shorten or lengthen, whatever the case may be necessary, the durations of the fifth power clock phase's P5′s evaluation and/or charge recovery intervals. All of these accommodations can be satisfied by simply reprogramming the bit patterns of the fifth-phase switch control signals SW5-1, SW5-2, . . ., SW5-M provided by the state machine 404.

From the foregoing description it should be clear that introducing the fifth power clock phase P5 among a quadrature four-phase power clock obviates the need for phase-correction buffers in converging-path adiabatic logic systems. The impact of eliminating the need for phase-correction buffers can be profound. For example, consider the N=8-bit parallel-prefix Brent-Kung adder depicted FIG. 10. To implement such an adder using adiabatic logic, 2 N−log₂N−2=11 logic gates (denoted by the black diamonds in FIG. 10) are needed and, at a minimum, 2N log₂N+log₂N−3N+2=29 phase-correction buffers (denoted by the white triangles) are required to maintain proper pipelining. In accordance with the present invention, by introducing just the single fifth power clock phase P5 all 17 buffers in bit columns 0, 2, 4 and 6 can be eliminated. Some, or even potentially all of the remaining data buffers can be eliminated by introducing even more clock phases. Although there is a slight overhead in creating the additional clock phases, the overhead can be amortized over may circuits.

While various embodiments of the present invention have been described, they have been presented by way of example and not limitation. It will be apparent to persons skilled in the relevant art that various changes in form and detail may be made to the exemplary embodiments without departing from the true spirit and scope of the invention. Accordingly, the scope of the invention should not be limited by the specifics of the exemplary embodiments but, instead, should be determined by the appended claims, including the full scope of equivalents to which such claims are entitled.

1. An adiabatic logic system, comprising:
a first path including a pipeline of first, second, third and fourth adiabatic logic gates controlled by first, second, third and fourth power clock phases P1, P2, P3 and P4;
a second path that converges with the first path at inputs of the fourth adiabatic logic gate, the second path including a fifth adiabatic logic gate controlled by a fifth power clock phase P5 having hold intervals that overlap evaluation intervals of the fourth power clock phase P4; and
a power clock generator configured to generate the first, second, third, fourth and fifth power clock phases P1, P2, P3, P4 and P5.

2. The adiabatic logic system of claim 1, wherein the power clock generator is operable to generate the fifth power clock phase P5 so that once generated and configured to control the fifth adiabatic logic gate the fifth adiabatic logic gate is able to honor a critical hold time required by the fourth adiabatic logic gate.

3. The adiabatic logic system of claim 2, wherein the power clock generator is operable to maximize durations of evaluation and/or charge recovery intervals of the fifth power clock phase P5 when generating the fifth power clock phase P5, yet once configured to control the fifth adiabatic logic gate the fifth adiabatic logic gate is still able to honor a critical hold time required by the fourth adiabatic logic.

4. The adiabatic logic system of claim 1, wherein the power clock generator comprises a stepwise power clock generator operable to vary a magnitude or magnitudes of one or more voltage steps of the fifth power clock phase P5 so that once generated and configured to control the fifth adiabatic logic gate the fifth adiabatic logic gate is able to honor a critical hold time required by the fourth adiabatic logic gate.

5. The adiabatic logic system of claim 1, wherein the power clock generator comprises a stepwise power clock generator operable to vary a duration or durations of one or more voltage steps of the fifth power clock phase P5 so that that once generated and configured to control the fifth adiabatic logic gate the fifth adiabatic logic gate is able to honor a critical hold time required by the fourth adiabatic logic gate.

6. The adiabatic logic system of claim 1, wherein the power clock generator is operable to generate the fifth power clock phase P5 so that once generated and configured to control the fifth adiabatic logic gate each hold interval of the fifth power clock phase P5 ends immediately upon the fourth adiabatic logic gate evaluating its inputs.

7. The adiabatic logic system of claim 1, wherein the power clock generator is operable to generate the fifth power clock phase P5 so that once generated and configured to control the fifth adiabatic logic gate each hold interval of the fifth power clock phase P5 begins immediately upon a magnitude of the fourth power clock phase P4 exceeding an absolute value of a threshold voltage of a PMOS transistor in the fourth adiabatic logic gate.

8. The adiabatic logic system of claim 1, wherein the adiabatic logic system comprises one or more additional converging paths that include one or more additional adiabatic logic gates, and the power clock generator is configured to generate one or more additional power clock phases for the one or more additional adiabatic logic gates.

9. A method of controlling an adiabatic logic system having two or more converging paths, comprising
generating first, second, third and fourth power clock phases P1, P2, P3 and P4 for a pipeline of first, second, third and fourth adiabatic logic gates configured in a first path;
generating a fifth power clock phase P5 for a fifth adiabatic logic gate configured in a second path;
conveying data from an output of the fifth adiabatic logic gate to an input of the fourth adiabatic logic gate; and
obviating a need for phase-correction buffers in the second path by controlling the fifth power clock phase P5 so that its hold intervals overlap evaluation intervals of the fourth power clock phase P4.

10. The method of claim 9, wherein generating the fifth power clock phase P5 includes ensuring that a critical hold time required by the fourth adiabatic logic gate is honored.

11. The method of claim 10, wherein generating the fifth power clock phase P5 comprises maximizing durations of evaluation and/or charge recovery intervals of the fifth power clock phase P5, yet once configured to control the fifth adiabatic logic gate the fifth adiabatic logic gate is still able to honor a critical hold time required by the fourth adiabatic logic gate.

12. The method of claim 9, wherein generating the fifth power clock phase P5 comprises:
stepwise generating the fifth power clock phase P5; and
varying a magnitude or magnitudes of one or more voltage steps of the fifth power clock phase P5 during stepwise generating the fifth power clock phase P5 so that once generated and configured to control the fifth adiabatic logic gate the fifth adiabatic logic gate is able to honor a critical hold time required by the fourth adiabatic logic gate.

13. The method of claim 9, wherein generating the fifth power clock phase P5 comprises:
stepwise generating the fifth power clock phase P5; and
varying a duration or durations of one or more voltage steps of the fifth power clock phase P5 during stepwise generating the fifth power clock phase P5 so that once generated and configured to control the fifth adiabatic logic gate the fifth adiabatic logic gate is able to honor a critical hold time required by the fourth adiabatic logic gate.

14. The method of claim 9, wherein generating the first, second, third and fourth power clock phases P1, P2, P3 and P4 and generating the fifth power clock phase P5 are performed so that once generated and configured to control the first, second, third, fourth and fifth adiabatic logic gates each hold interval of the fifth power clock phase P5 ends immediately upon the fourth adiabatic logic gate evaluating its inputs.

15. The method of claim 9, wherein generating the first, second, third and fourth power clock phases P1, P2, P3 and P4 and generating the fifth power clock phase P5 are performed so that once generated and configured to control the first, second, third, fourth and fifth adiabatic logic gates each hold interval of the fifth power clock phase P5 begins immediately upon a magnitude of the fourth power clock phase P4 exceeding an absolute value of a threshold voltage of a PMOS transistor in the fourth adiabatic logic gate.

16. The method of claim 9, further comprising generating one or more additional power clock phases for one or more additional adiabatic logic gates configured in one or more additional converging paths.
